(19) United States
(12) Patent Application Publication
(10) Pub. No.: US 2019/0051554 A1
(43) Pub. Date: Feb. 14, 2019

(54) Wafer Support Assembly Including Ion Implantation Mask Structure

(71) Applicant: Samsung Electronics Co., Ltd., Suwon-si (KR)

(72) Inventors: Hyun Chul Song, Seoul (KR); Tae Gon Kim, Seoul (KR); Kyung In Choi, Seoul (KR); Sun Hong Choi, Hwaseong-si (KR); HanMei Choi, Seoul (KR); Sang Hoon Han, Seoul (KR)

(21) Appl. No.: 15/834,676

(22) Filed: Dec. 7, 2017

(30) Foreign Application Priority Data
Aug. 8, 2017 (KR) 10-2017-0100457

(51) Int. Cl. H01L 21/687; H01L 21/265; H01L 21/67; H01L 21/02; B23B 31/02; H01L 21/683

(52) U.S. Cl. CPC H01L 21/68735; H01L 21/265; H01L 21/6833; H01L 21/02021; B23B 31/02; H01L 21/67109

(57) ABSTRACT

A wafer support assembly can include a wafer chuck including a first surface and a second surface, where the first surface can have a central region that is configured to hold a wafer during ion implantation into the wafer, and an edge region surrounding the central region beyond an edge of the wafer when held in the central region, and the second surface opposing the first surface. An edge mask structure can cover at least a portion of the edge region of the first surface, where the edge mask structure can have a mask body with an inclined side surface facing the central region.

### CROSS-REFERENCE TO RELATED APPLICATION

This application claims benefit of priority to Korean Patent Application No. 10-2017-0100457, filed on Aug. 8, 2017 in the Korean Intellectual Property Office, the disclosure of which is incorporated herein by reference in its entirety.

### FIELD

The inventive concept relates to semiconductor processing equipment in general, and more particularly, to ion implantation semiconductor fabrication processing equipment.

### BACKGROUND

To manufacture semiconductor devices, ions may be implanted into a wafer to change the physical properties of a semiconductor region within the wafer. The ion implantation process may include generating and accelerating an ion beam to impinge onto the wafer. While performing the ion implantation process, the wafer may be fixed to a wafer chuck, such as an electrostatic chuck. A conventional wafer chuck used in an ion implantation process may have difficulty in uniformly heating a wafer having an increased diameter.

### SUMMARY

Embodiments according to the inventive concept, may provide a wafer support assembly including an ion implantation mask structure. Pursuant to these embodiments, a wafer support assembly can include a wafer chuck including a first surface and a second surface, where the first surface can have a central region that is configured to hold a wafer during ion implantation into the wafer, and an edge region surrounding the central region beyond an edge of the wafer when held in the central region, and the second surface opposing the first surface. An edge mask structure can cover at least a portion of the edge region of the first surface, where the edge mask structure can have a mask body with an inclined side surface facing the central region.

In some embodiments, a wafer support assembly can include a wafer chuck that can include a first surface and a second surface, where the first surface may have a central region configured to hold a wafer during ion implantation into the wafer, and an edge region surrounding the central region beyond an edge of the wafer when held in the central region, and the second surface opposing the first surface, wherein the second surface can have a width less than a width of the first surface. An edge mask structure can have a mask body overlapping the edge region.

In some embodiments, a semiconductor processing apparatus can include a process chamber and a wafer support assembly disposed within the process chamber. The wafer support assembly can include a support body, a chuck support connected to the support body, the chuck support having a rotary shaft, and a wafer chuck including a first surface and a second surface, the first surface having a central region configured to hold a wafer during ion implantation into the wafer, and an edge region surrounding the central region beyond an edge of the wafer when held in the central region. The second surface can be opposite the first surface, and the second surface can be coupled to the chuck support. An edge mask structure can include a mask body that covers at least a portion of the edge region of the first surface.

### BRIEF DESCRIPTION OF DRAWINGS

The above, and other aspects, features, and advantages of the present disclosure will be more clearly understood from the following detailed description when taken in conjunction with the accompanying drawings, in which:

FIG. 1 illustrates a diagram of an ion implantation equipment, according to an example embodiment;

FIGS. 2A, 2B, and 2C are longitudinal section views illustrating a wafer support assembly within an ion implantation equipment, according to an example embodiment;

FIG. 3A is a plan view illustrating a wafer chuck of a wafer support assembly within an ion implantation equipment, according to an example embodiment;

FIG. 3B is a plan view illustrating an edge mask structure of a wafer support assembly within an ion implantation equipment, according to an example embodiment;

FIG. 4 is an enlarged view of part A of FIG. 2B;

FIG. 5A is an enlarged view of part B of FIG. 4;

FIG. 5B is an enlarged view illustrating a modified example of an edge mask structure of a wafer support assembly within an ion implantation equipment, according to an example embodiment;

FIG. 6A is an enlarged view illustrating another modified example of an edge mask structure of a wafer support assembly within an ion implantation equipment, according to an example embodiment;

FIG. 6B is an enlarged view illustrating another modified example of an edge mask structure of a wafer support assembly within an ion implantation equipment, according to an example embodiment;

FIG. 7 is a longitudinal section view illustrating a modified example of a wafer support assembly within an ion implantation equipment, according to an example embodiment; and

FIGS. 8A and 8B are plan views illustrating other modified examples of an edge mask structure of a wafer support assembly within an ion implantation equipment, according to example embodiments.

### DETAILED DESCRIPTION

Embodiments of the present inventive subject matter are described fully hereinafter with reference to the accompanying drawings, in which embodiments of the present inventive subject matter are shown. This present inventive subject matter may, however, be embodied in many different forms and should not be construed as limited to the embodiments set forth herein. Rather, these embodiments are provided so that this disclosure will be thorough and complete, and will fully convey the scope of the present inventive subject matter to those skilled in the art. Like numbers refer to like elements throughout.

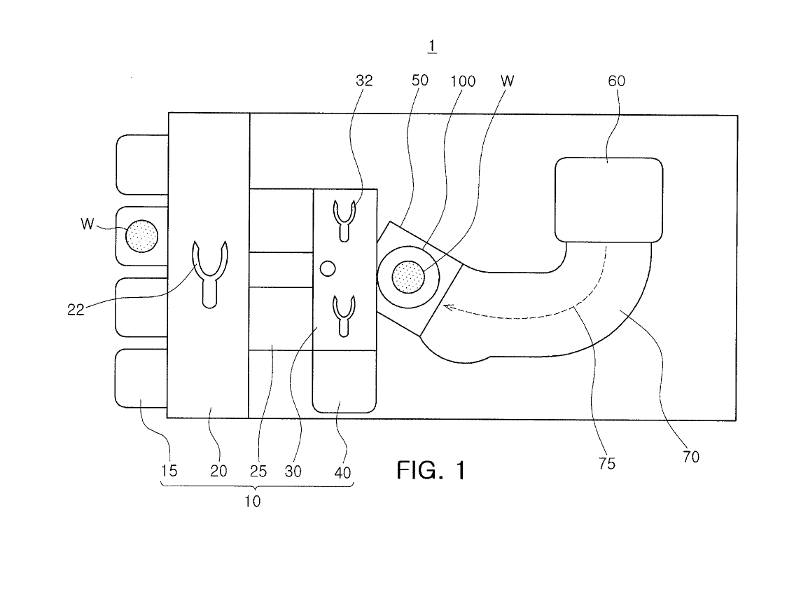

An ion implantation equipment, according to an example embodiment of the present inventive concept, will be described with reference to FIG. 1. FIG. 1 is a diagram of an ion implantation equipment including a wafer support assembly (sometimes referred to hereinafter collectively as “ion implantation equipment,”) according to an example embodiment.

Referring to FIG. 1, an ion implantation equipment 1, according to an example embodiment, may include a wafer transfer apparatus 10, a process chamber 50 disposed on one side of the wafer transfer apparatus 10, a wafer support assembly 100 disposed within the process chamber 50, an ion source unit 60 generating ions, and an ion beam line 70 accelerating ions generated by the ion source unit 60 to generate an ion beam 75 and radiating the ion beam 75 to the wafer support assembly 100.

The wafer transfer apparatus 10 may transfer a wafer to implant ions within the process chamber 50 or may remove an ion-implanted wafer from the process chamber 50. For example, the wafer transfer apparatus 10 may include a cassette station 15, a standby transfer unit 20 disposed on one side of the cassette station 15, a load lock chamber 25 disposed on one side of the standby transfer unit 20, and an intermediate transfer chamber 30 disposed on one side of the load lock chamber 25 as shown in FIG. 1 (although other arrangements may be used in embodiments according to the inventive concept).

The standby transfer unit 20 may include a first robot arm 22 that may transfer a wafer W within the cassette station 15 into the load lock chamber 25 or may transfer the wafer W within the load lock chamber 25 into the cassette station 15. The intermediate transfer chamber 30 may be in close contact with the process chamber 50, or may be connected thereto.

The intermediate transfer chamber 30 may include a second robot arm 32 that may transfer a wafer within the load lock chamber 25 into the process chamber 50 or may transfer an ion-implanted wafer W within the process chamber 50 into the load lock chamber 25.

In an example embodiment, the wafer transfer apparatus 10 may include a preheating station 40 disposed on one side of the intermediate transfer chamber 30. To perform an ion implantation process, the wafer W within the process chamber 50 may be preheated by the preheating station 40, loaded into the process chamber 50, and placed on the wafer support assembly 100 within the process chamber 50. The preheating station 40 may reduce a time required to heat the wafer W in the wafer support assembly 100, thus decreasing an ion implantation process time. As a result, productivity may be increased.

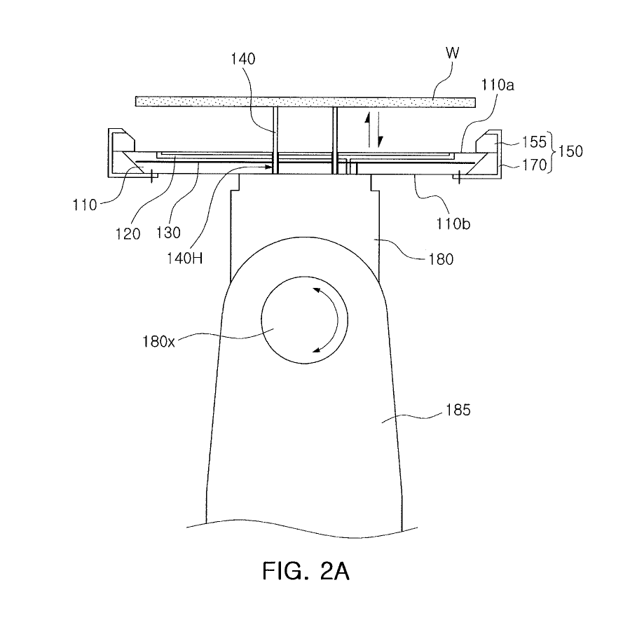

FIGS. 2A, 2B, and 2C are longitudinal section views illustrating the wafer support assembly 100.

Referring to FIGS. 2A, 2B, and 2C, the wafer support assembly 100 may include a wafer chuck 110 including a first surface 110a and a second surface 110b opposing each other, and an edge mask structure 150 coupled to the wafer chuck 110. The wafer support assembly 100 may include a chuck support 180 connected to a portion of the second surface 110b of the wafer chuck 110 to support the wafer chuck 110, and a support body 185 disposed below the chuck support 180 and connected to the chuck support 180. The chuck support 180 may have a rotary shaft 180x connected to the support body 185.

To perform the ion implantation process, the wafer W transferred into the process chamber 50 from the intermediate transfer chamber 30 by the second robot arm 32 within the intermediate transfer chamber 30 may be placed on lift pins 140 moved to an upper portion of the wafer chuck 110 through lift pin holes 140H passing through the wafer chuck 110. The wafer W placed on the lift pins 140 as illustrated in FIG. 2A may be placed on the first surface 110a of the wafer chuck 110 with the lift pins 140 are recessed into the lift pin holes 140H, as illustrated in FIG. 2B.

The wafer chuck 110 may be an electrostatic chuck including a heating member 130, such as a heating coil or the like, and a gas channel 120. The wafer W may be fixed to the first surface 110a of the wafer chuck 110.

The wafer chuck 110 may have a width narrowing from the first surface 110a toward the second surface 110b. For example, the wafer chuck 110 may have an inclined side surface such that a width of the wafer chuck 110 may narrow from the first surface 110a toward the second surface 110b.

After the wafer W is placed on the first surface 110a of the wafer chuck 110, the chuck support 180 may rotate or move in a direction in which the ion beam 75 described above with reference to FIG. 1 may be radiated. Thus, as the chuck support 180 rotates in a downward direction around the rotary shaft 180x coupled to the support body 185, the wafer chuck 110 and the wafer W may also move. Thus, the wafer W may be positioned in the path of the ion beam 75 described above with reference to FIG. 1 may be radiated.

The rotation and movement of the chuck support 180 as described above may be determined according to a predetermined angle between a surface of the wafer W and the ion beam 75. For example, FIG. 2C illustrates the ion beam 75 radiated in a direction perpendicular to the surface of the wafer W. However, example embodiments of the present inventive concept are not limited thereto. For example, when performing the ion implantation process, the chuck support 180 may be rotated or moved such that the surface of the wafer W may be inclined with respect to the radiated ion beam 75.

The wafer W may be heated by the heating member 130 within the wafer chuck 110. The temperature of the wafer W may be properly adjusted or lowered by gas, such as nitrogen gas or the like, flowing through the gas channel 120 within the wafer chuck 110. For example, the temperature of the wafer W may be adjusted by a combination of heating (using the heating member 130) and cooling (using the gas channel 120). Thus, the ion implantation process may be performed by radiating the ion beam 75 to the surface of the wafer W heated by the heating member 130 within the wafer chuck 110.

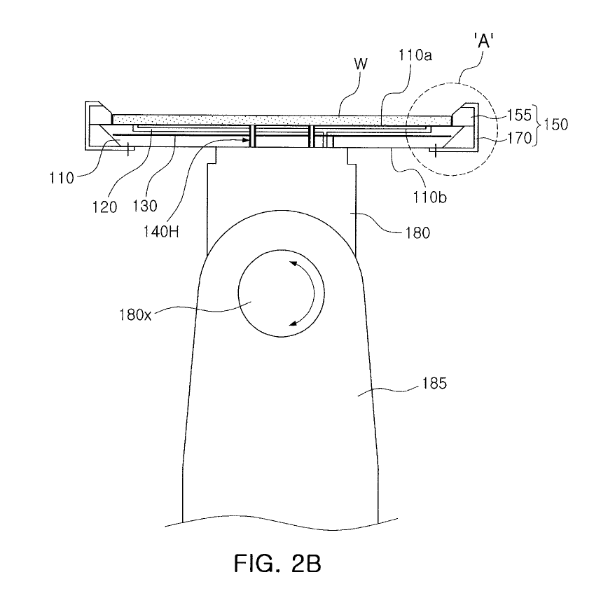

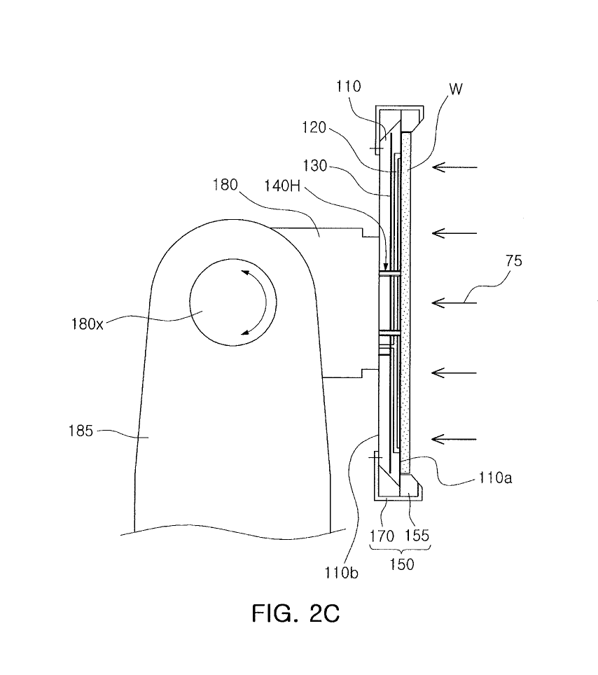

Next, the wafer chuck 110 will be described with reference to FIGS. 3A and 3B. FIG. 3A is a plan view illustrating the wafer chuck 110 of the wafer support assembly 100, and FIG. 3B is a plan view illustrating the edge mask structure 150 of the wafer support assembly 100.

Referring first to FIG. 3A, the first surface 110a of the wafer chuck 110 may have a central region CA in which the wafer W may be placed, and an edge region EA surrounding the central region CA. The edge region EA may have a ring shape.

Referring next to FIGS. 3A and 3B, the edge mask structure 150 may include a mask body 155 having a ring shape and a connector 170 connected to the mask body 155. The edge mask structure 150 may be formed of a material having strong wear resistance to an ion beam, for example, a material including graphite.

The connector 170 may be provided as a plurality of connectors 170. The connectors 170 may be spaced apart from each other. For example, the connector 170 may be disposed at 90°, 180°, or 270°, based on a direction in which the wafer W may be transferred by the wafer transfer apparatus 10 of FIG. 1.

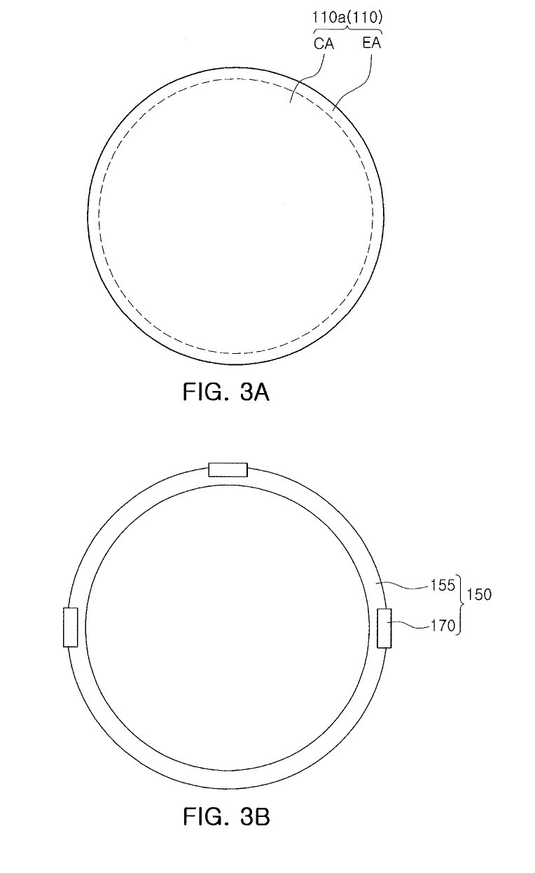

Subsequently, the edge mask structure 150 will be described below. FIG. 4 is an enlarged view of part A of FIG. 2B.

Referring to FIGS. 2A through 2C, 3A, 3B, and 4, as described above, the edge mask structure 150 may include the mask body 155 and the connector 170.

The edge mask structure 150 may expose the central region CA of the first surface 110a of the wafer chuck 110, may cover the edge region EA of the first surface 110a of the wafer chuck 110, and may be coupled to the second surface 110b of the wafer chuck 110.

The mask body 155 may cover the edge region EA of the first surface 110a of the wafer chuck 110. The mask body 155 may overlap the edge region EA of the first surface 110a of the wafer chuck 110.

The connector 170 of the edge mask structure 150 may be connected to the mask body 155, and may extend to the second surface 110b of the wafer chuck 110 to be coupled to the second surface 110b. The connector 170 may be connected to an upper surface and a side surface of the mask body 155. The connector 170 may be coupled to the second surface 110b by a screw 172 or other device.

The mask body 155 may include a lower region 157 and an upper region 160 disposed on the lower region 157. The upper region 160 may have a width less than that of the lower region 157.

The lower region 157 may have a lower internal surface 157S facing the wafer W placed in the central region CA of the wafer chuck 110. The lower region 157 may have substantially the same thickness as that of the wafer W placed in the central region CA of the wafer chuck 110. The lower internal surface 157S may be perpendicular to a lower surface of the lower region 157.

The upper region 160 may have an upper internal surface 160S having a slope different from that of the lower internal surface 157S. The upper internal surface 160S may form an obtuse angle θ with respect to an upper surface 160U of the upper region 160, and may form an inclined side surface. The obtuse angle θ between the upper internal surface 160S and the upper surface 160U of the upper region 160 may be 135° or greater.

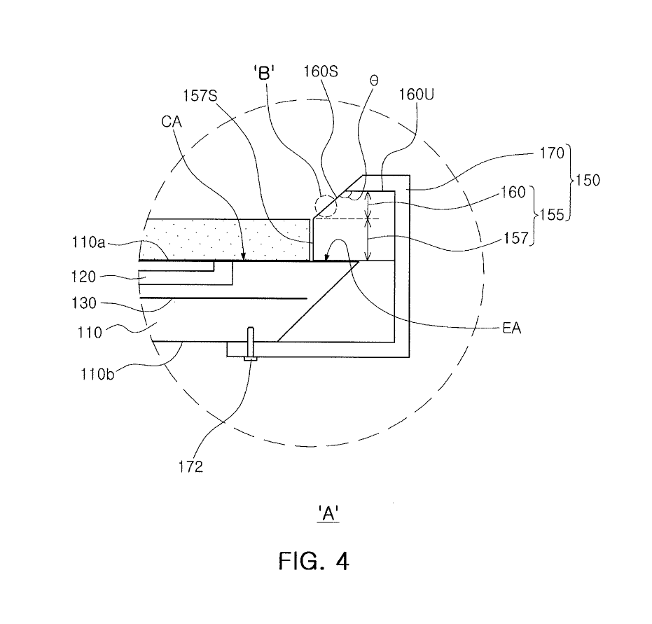

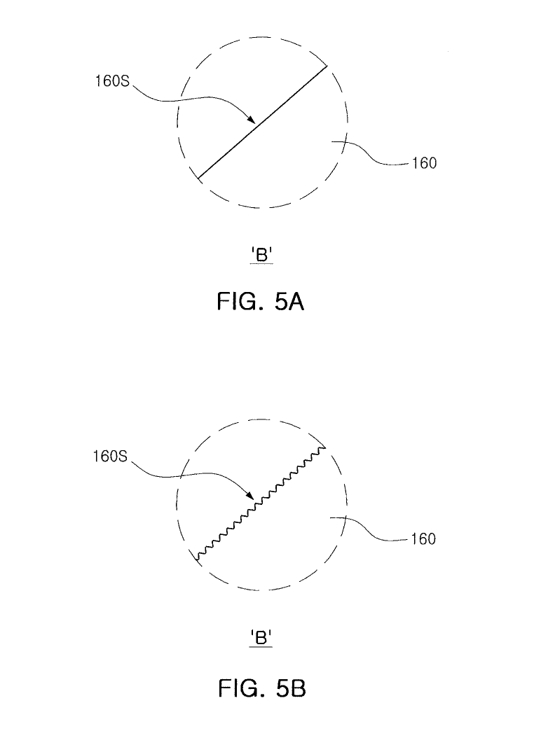

Various examples of the upper internal surface 160S will be described with reference to FIGS. 5A and 5B, respectively. FIGS. 5A and 5B are enlarged views of part B of FIG. 4.

In an example embodiment, the upper internal surface 160S may be relatively smooth as illustrated in FIG. 5A. However, example embodiments of the present inventive concept are not limited thereto. For example, the upper internal surface 160S may be relatively rough (compared to the surface shown in FIG. 5A) as illustrated in FIG. 5B. For example, the upper internal surface 160S may be beveled so as to scatter the ion beam 75 of FIG. 2C radiated in a direction toward the wafer W fixed to the wafer chuck 110 of FIG. 2C. Thus, an amount of the ion beam 75 of FIG. 2C reflected from the upper internal surface 160S to be directed toward the wafer W may be significantly reduced, thereby increasing the ion implantation distribution characteristics of the wafer W of FIG. 2C.

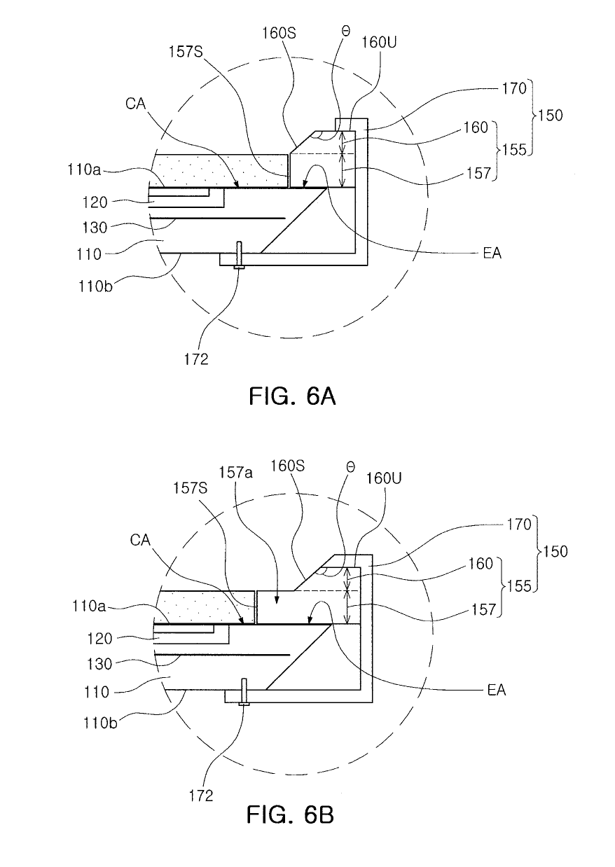

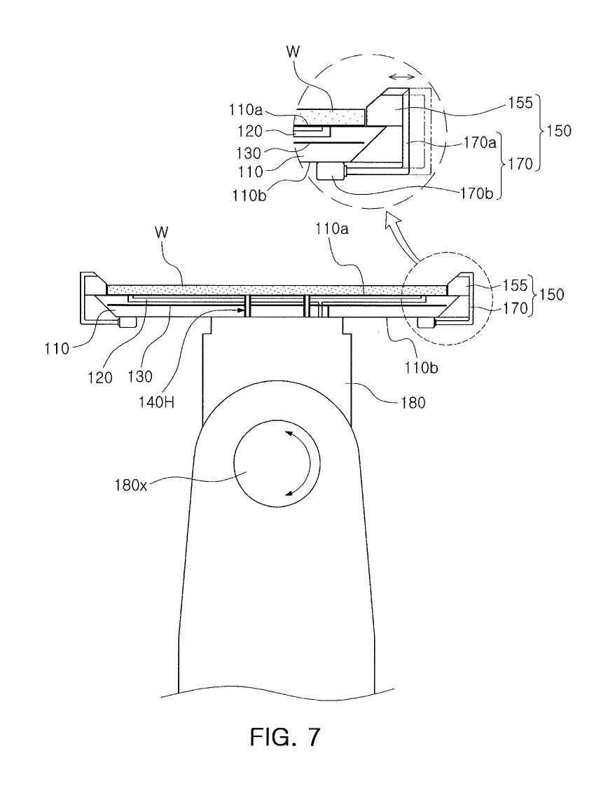

In an example embodiment, the entirety of the upper surface 160U of the mask body 155 may be covered by the connector 170 as illustrated in FIG. 4. However, example embodiments of the present inventive concept are not limited thereto. A modified example of the connector 170 will be described with reference to FIG. 6A.

Referring to FIG. 6A, the connector 170 may cover a portion of the upper surface 160U of the mask body 155. For example, the connector 170 may expose a portion of the upper surface 160U of the mask body 155 closest to the wafer W, and may cover a portion of the upper surface 160U more distant from the wafer W.

In an example embodiment, the upper region 160 of the mask body 155 may cover the entirety of the lower region 157 and may have an increasingly narrowing width as illustrated in FIG. 4. However, example embodiments of the present inventive concept are not limited thereto. A modified example of the upper region 160 will be described with reference to FIG. 6B.

Referring to FIG. 6B, the upper region 160 may extend upwardly from a portion of the lower region 157. Thus, the lower region 157 may include a region 157a extending with a predetermined thickness in a direction toward the wafer W from a portion of the lower region 157 overlapping the upper region 160. The extending region 157a may have substantially the same thickness as that of the wafer W.

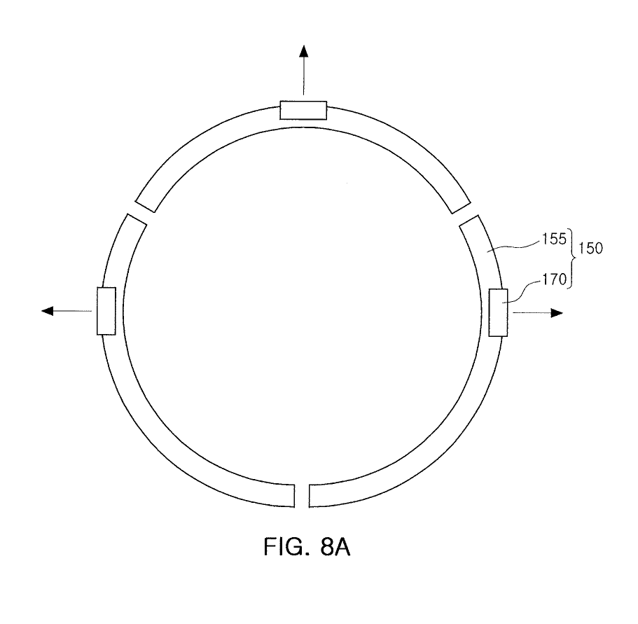

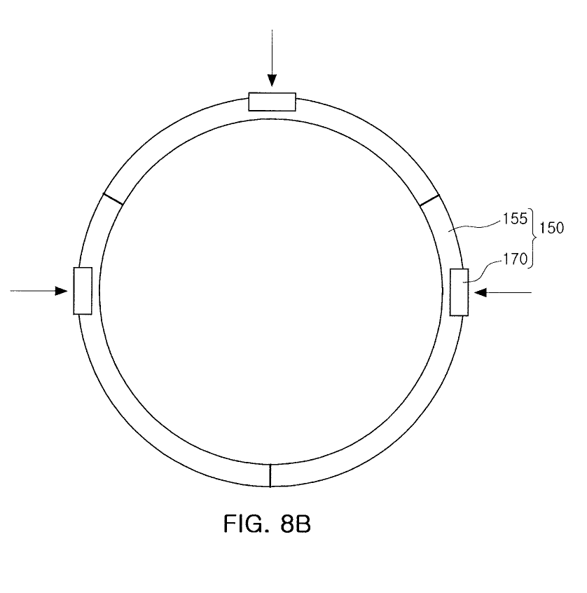

Next, modified examples of the wafer support assembly will be described with reference to FIGS. 7, 8A, and 8B. FIG. 7 is a longitudinal section view illustrating another modified example of an edge mask structure of a wafer support assembly within an ion implantation equipment, according to an example embodiment, and FIGS. 8A and 8B are plan views illustrating other modified examples of an edge mask structure of a wafer support assembly within an ion implantation equipment, according to an example embodiment.

Referring to FIGS. 7, 8A, and 8B, the edge mask structure 150 may include a mask body 155 and a connector 170.

The mask body 155 may be provided as a plurality of mask bodies 155. For example, the mask body 155 may be divided into three mask bodies 155 as illustrated in FIG. 8A. However, example embodiments of the present inventive concept are not limited thereto. For example, the mask bodies 155 may also be divided into two or four or more mask bodies 155.

The connector 170 may be provided in the number of the mask bodies 155 separated from each other.

The connector 170 may include a connection support portion 170a connected or attached to the mask body 155, and a driving motor 170b attached or coupled to the second surface 110b of the wafer chuck 110 to move the connection support portion 170a. The mask body 155 provided as the mask bodies 155 may be movable together with a movement of the connection support portion 170a moved by the driving motor 170b. For example, depending on an operation of the driving motor 170b, the mask body 155 provided as the mask bodies 155 as illustrated in FIG. 8A may be moved in an inward direction as illustrated in FIG. 8B. Thus, a void between the wafer W and the edge mask structure 150 may be significantly reduced, thereby significantly lessening damage to the wafer chuck 110 due to an ion beam radiated to the wafer W by the ion implantation process.

According to example embodiments, the edge mask structure 150 may protect the edge region EA of the wafer chuck 110 having the width greater than that of the wafer W from an ion beam used in the ion implantation process. Thus, deterioration of the wafer chuck 110 due to exposure to the ion beam 75 may be reduced, thereby extending the lifespan of the wafer chuck 110. As a result, productivity may be increased.

According to example embodiments, the wafer chuck 110 including the heating member 130 may have the width greater than that of the wafer W, and accordingly, the wafer W used in the ion implantation process may be heated to an edge thereof by heat generated by the heating member 130 within the wafer chuck 110. Thus, the wafer chuck 110 may heat the entirety of the wafer W more uniformly. As a result, the ion implantation process may be performed on the more uniformly heated wafer W, and the ion implantation distribution characteristics of the wafer W may be increased.

As set forth above, according to example embodiments of the present inventive concept, a wafer support assembly and an ion implantation equipment including the same may be provided.

The wafer support assembly may include a wafer chuck having a width greater than that of a wafer used in an ion implantation process, and an edge mask structure covering an edge region of the wafer chuck.

The edge mask structure may protect the edge region of the wafer chuck having the width greater than that of the wafer from an ion beam used in the ion implantation process. Thus, the wafer chuck may be prevented from being deteriorated by the ion beam, thereby extending the lifespan of the wafer chuck. As a result, productivity may be increased.

Since the wafer chuck has the width greater than that of the wafer, the wafer used in the ion implantation process may be heated to an edge thereof. Thus, the wafer chuck may heat the entirety of the wafer more uniformly. As a result, the ion implantation process may be performed on the uniformly heated wafer, and the ion implantation distribution characteristics of the wafer may be increased.

While exemplary embodiments have been shown and described above, it will be apparent to those skilled in the art that modifications and variations could be made without departing from the scope of the present inventive concept, as defined by the appended claims.

What is claimed:

1. A wafer support assembly, comprising:
a wafer chuck including a first surface and a second surface, the first surface having a central region configured to hold a wafer during ion implantation into the wafer, and an edge region surrounding the central region beyond an edge of the wafer when held in the central region, and the second surface opposing the first surface; and
an edge mask structure covering at least a portion of the edge region of the first surface, the edge mask structure having a mask body with an inclined side surface facing the central region.

2. The wafer support assembly of claim 1, wherein the mask body includes a lower region and an upper region disposed on the lower region, and the upper region has a width less than a width of the lower region.

3. The wafer support assembly of claim 2, wherein the lower region has a lower internal surface facing the central region of the wafer chuck, and the upper region including the inclined side surface comprising an upper internal surface having a slope different from a slope of the lower internal surface.

4. The wafer support assembly of claim 3, wherein the lower internal surface is perpendicular to a lower surface of the lower region, and the upper internal surface forms an obtuse angle with an uppermost surface of the upper region, to form the inclined side surface.

5. The wafer support assembly of claim 4, wherein the obtuse angle is 135° or greater and less than 180°.

6. The wafer support assembly of claim 1, wherein the edge mask structure further includes a connector connected to the mask body and coupled to the second surface of the wafer chuck.

7. The wafer support assembly of claim 6, wherein the mask body is divided into a plurality of mask bodies, and the connector includes a connection support portion connected to the mask body, and a driving motor coupled to the second surface of the wafer chuck, the drive motor configured to move the connection support portion toward/away from the central region, the mask body being movable with the connection support portion.

8. The wafer support assembly of claim 1, wherein the wafer chuck has a width narrowing from the first surface toward the second surface.

9. The wafer support assembly of claim 1, wherein the wafer chuck is an electrostatic chuck including a heating member and a gas channel therein.

10. A wafer support assembly, comprising:
a wafer chuck including a first surface and a second surface, the first surface having a central region configured to hold a wafer during ion implantation into the wafer, and an edge region surrounding the central region beyond an edge of the wafer when held in the central region, and the second surface opposing the first surface, wherein the second surface has a width less than a width of the first surface; and
an edge mask structure having a mask body overlapping the edge region.

11. The wafer support assembly of claim 10, wherein the edge mask structure further includes a connector connected to the mask body, the connector extending to the second surface of the wafer chuck and coupled to the second surface.

12. The wafer support assembly of claim 11, wherein the connector is connected to an upper surface and a side surface of the mask body.

13. The wafer support assembly of claim 11, wherein the mask body includes a lower region and an upper region disposed on the lower region, the lower region has a lower internal surface facing the central region, the lower internal surface being perpendicular to a lowest surface of the lower region, and the upper region has an upper internal surface forming an obtuse angle with respect to an uppermost surface of the upper region.

14. The wafer support assembly of claim 13, wherein the lower region includes a region extending with a predetermined thickness in a direction toward the central region from a portion of the lower region overlapping the upper region.

15. The wafer support assembly of claim 13, wherein the upper internal surface is beveled toward the central region.

16. A semiconductor processing apparatus, comprising:
a process chamber; and
a wafer support assembly disposed within the process chamber,
wherein the wafer support assembly includes:
a support body;
a chuck support connected to the support body, the chuck support having a rotary shaft;
a wafer chuck including a first surface and a second surface, the first surface having a central region configured to hold a wafer during ion implantation into the wafer, and an edge region surrounding the central region beyond an edge of the wafer when held in the central region, the second surface opposing the first surface, and the second surface being coupled to the chuck support; and
an edge mask structure including a mask body covering at least a portion of the edge region of the first surface.

17. The semiconductor processing apparatus of claim 16, wherein the first surface has a width greater than a width of the second surface.

18. The semiconductor processing apparatus of claim 16, wherein the mask body includes a lower region and an upper region disposed on the lower region, the lower region has a lower internal surface facing the central region of the first surface, and the upper region has an upper internal surface forming an obtuse angle with an uppermost surface of the upper region.

19. The semiconductor processing apparatus of claim 16, wherein the edge mask structure further includes:
a connector connected to the mask body, the connector extending to the second surface of the wafer chuck and coupled the second surface.

20. The semiconductor processing apparatus of claim 16, further comprising:
a wafer transfer apparatus configured to transfer the wafer to an upper portion of the wafer chuck; and
an ion beam source configured to radiate an ion beam toward the central region, wherein the wafer transfer apparatus includes a preheating station preheating the wafer before transferring the wafer to the upper portion of the wafer chuck, and the wafer chuck includes a heating member configured to heat the wafer placed in the central region.
